(19) United States
(12) Patent Application Publication
(10) Pub. No.: US 2012/0282478 A1
(43) Pub. Date: Nov. 8, 2012

(54) METHOD AND APPARATUS FOR THE MULTI-LAYER AND MULTI-COMPONENT COATING OF THIN FILMS ON SUBSTRATES, AND MULTI-LAYER AND MULTI-COMPONENT COATINGS

(75) Inventors: Joaquín Oseguera Peña, Cuautitlán Izcalli (MX); Alejandro Rojo Valerio, Toluca (MX); Jorge Alberto Acosta Flores, Nueva Tenochtitlán (MX); Olimpia Salas Martinez, Tepotzotlán (MX); Dulce Viridiana Melo Maximo, Cuautitlán Izcalli (MX); Jorge Alvarez Diaz, Cuernavaca (MX)

(73) Assignee: INSTITUTO TECNOLOGICO Y DE ESTUDIOS SUPERIORES DE MONTERREY, Margarita Maza de Juárez (MX)

(21) Appl. No.: 13/501,439

(22) PCT Filed: Sep. 1, 2010
(86) PCT No.: PCT/IB2010/002166

§ 371 Date: Jul. 30, 2012

(30) Foreign Application Priority Data
Sep. 3, 2009 (MX) MX/A/2009/009425

(51) Int. Cl. C23C 14/02; B32B 15/04; B32B 5/00

(52) U.S. Cl. 428/472.1; 428/472.2; 427/534; 118/50

(57) ABSTRACT

The present invention pertains to a process for depositing multi-component and nanostructured thin films. Various parameters are monitored during the process to produce the structure of the thin films, on one hand the residence time of the gas mixture in the reactor is controlled by the pumping rate, on the other side to generate the plasma direct current (DC) or radio frequency (RF) sources are used, plus the combination of three unbalanced magnetrons allows alternative emission of elements that make up the multi-component and nanostructured films. The process is monitored by an optical emission spectrometer (EOE) and a Langmuir probe (SL), the EOE can follow the emission corresponding to the electronic transitions of atoms and molecules in the plasma. Emissions occur in the visible, infrared and ultraviolet domains. The relationships between spectral networks of different elements have been identified that ensure structural characteristics of thin films. Through SL, operating conditions have been identified by measuring the electron temperature and measuring the density of electrons. It was decided in the prototype to make this measurement at significantly important points in the process.

### SUMMARY OF THE INVENTION

The present invention pertains to a process for depositing multi-component and nanostructured thin films. Various parameters are monitored during the process to produce the structure of the thin films, on one hand the residence time of the gas mixture in the reactor is controlled by the pumping rate, on the other side to generate the plasma direct current (DC) or radio frequency (RF) sources are used, plus the combination of three unbalanced magnetrons allows alternative emission of elements that make up the multi-component and nanostructured films. The process is monitored by an optical emission spectrometer (EOE) and a Langmuir probe (SL), the EOE can follow the emission corresponding to the electronic transitions of atoms and molecules in the plasma. Emissions occur in the visible, infrared and ultraviolet domains. The relationships between spectral networks of different elements have been identified that ensure structural characteristics of thin films. Through SL, operating conditions have been identified by measuring the electron temperature and measuring the density of electrons. It was decided in the prototype to make this measurement at significantly important points in the process.

### BACKGROUND OF THE INVENTION

The invention relates to the physical vapor deposition process (in English Physical Vapor Deposition, PVD), in this type of process thin films are formed on substrates of various materials; it is well known that in these processes plasma forms at low pressures, in our case we sought that they were between 1 and 3 Pa, the plasma is produced by generating a potential difference between the reactor walls and the piece being pulverized, which we call blank; the potential difference can be between 600 and 1000 V. Ions in plasma dissipate their energy and pulverize the blank. The ions gain kinetic energy due to the combined presence of the electric field and magnetic field. The magnetic field is produced by means of a magnet configuration that is below the blank. Vapor emission from the blank is the precursor of nuclei generation in a substrate which is sought to be coated. Coalescence of the germs produces the columnar structures which constitute the thin films.

It is known that the properties of the films are dependent on operating parameters. Properties such as hardness, adhesion, reflection and refraction indexes are the result of operating parameters. The role that the coating shall perform imposes properties that have to be produced on the film. Several examples in the field of mechanics, electronics or optics make up the application of coatings.

The production of thin films with specific attributes to perform functions on a substrate has been sought through control of process variables. Two diagnostic elements are very important: monitoring by an optical emission spectrometer and measurement of the electrons temperature and density of ions.

The present invention features means of monitoring the production of specific structures through relationships between spectral lines of elements generated in the plasma, also an arrangement of magnetrons has been constructed such that the part can be coated forming multilayers, the transport of the parts in the chamber as well as appropriately introducing mixtures of elements such as nitrogen and oxygen in the plasma have allowed forming films which composition and stoichiometry can be graduated, thus generating multilayer and multi-component films. Another object covered in the present invention is to provide a methodology for the construction of multi-component and multilayer film architectures. Specifically, methodologies are disclosed to form multi-component CrN and AlN films, these films can be graduated or generate nanostructured composites: Cr→CrN and/or Al+AlN. They are useful in mechanical components subject to friction and wear.

Also disclosed are methodologies for manufacturing coatings for applications against catastrophic corrosion, a phenomenon known as “metal dusting”. We have developed coating architectures on special steels such as HK40 or H13. These steels are widely used in petrochemical plant pipelines, reforming plants and in iron direct reduction processes. Coatings have been produced with an adhesion layer of Cr or Al and an oxide of Cr₂O₃ or Al₂O₃, this compact oxide layer on the surface produces a means that limits carbon flow into the alloy, thereby limiting catastrophic corrosion.

### SUMMARY OF THE INVENTION

Disclosed is the design and construction of an experimental prototype for physical vapor deposition. In the disclosure of the prototype we consider the functional systems whose interaction results in the formation of multilayer and multi-component films. The system consists of subsystems, one known as gas extraction, another of power supply, and finally a plasma characterization subsystem. The functional design of the prototype produces multi-component and/or nanostructured thin films. Essential and original aspects in the design such as the introduction of the sample to the area affected by the plasma, heating the chamber, the introduction of nitrogen in the area near the plasma, the interchangeable CD and RF power supply, plasma diagnosis in relevant regions, the residence time of species in the chamber are disclosed in detail. The procedure for the synthesis of graded thin films of CrN and Al+AlN composites is also disclosed. Based on characterization of plasma original procedures are disclosed to achieve the formation of nitride thin films which have been made particularly, but not restrictively, on steel substrates, for example: H13 or 1045, the use of these materials is not restrictive in the context of the applications. Methodologies also are disclosed for the formation of stoichiometric oxides on special steel substrates such as HK40. We describe the process for forming a succession of Al/Al₂O₃ or Cr/Cr₂O₃ layers.

### DESCRIPTION OF THE FIGURES

FIG. 1. General scheme of the prototype.

1. Mechanical and turbomolecular pumps controller.

2. Mechanical pump.

3. Turbomolecular pump.

4. Three-way, three position valve.

5. Straight angle valve.

6. Heating lamp.

7. Mass flow controllers command.

8. Mass flow controllers.

9. Gas tanks.

10. Gas mixer.

11. Mixed gases supply.

12. Nitrogen supply close to blanks.

13. Direct current or radio frequency source.

14. Unbalanced magnetrons.

15. Sample holder.

16. Rotation of the sample holder.

17. Data acquisition unit of the Langmuir probe.

18. Langmuir probe.

19. Photomultiplier.

20. Monochromator or optical emission spectrometer.

21. Pressure Gauges.

FIG. 2. Detailed view of the extraction and gas supply system.

FIG. 3. Gas supply subsystem.

FIG. 4. Power supply system.

a) Direct current.

b) Radio frequency.

FIG. 5. Impedance setting diagram.

FIG. 6. Specific diagram of connections for the delivery of radiofrequency energy from the controller to the magnetron.

FIG. 7. Plasma analysis system. Langmuir probe.

FIG. 8. Position of Langmuir probe for plasma diagnosis.

a) Measured with reference to the height.

b) Measured with reference to the radius.

FIG. 9. Optical emission spectrometer.

FIG. 10. Architecture design of films for wear functional purposes.

FIG. 11. Setpoints for the manufacture of thin films.

FIG. 12. Optical emission spectra for plasma diagnostics. Variations in voltage.

FIG. 13. Optical emission spectra for plasma diagnostics. Variations in the percentage of nitrogen in the mixture.

FIG. 14. Optical emission spectra for plasma diagnostics. Variations in pressure.

FIG. 15. Optical emission spectra for plasma diagnostics. Cr emission and turning into the reactive mode for CrN synthesis.

FIG. 16. Optical emission spectra for plasma diagnostics. Al emission and turning into the reactive mode for AlN synthesis.

FIG. 17. CrN thin film image obtained by scanning electron microscopy.

FIG. 18. CrN X-ray diffraction spectrum.

FIG. 19. Scanning electron microscopy images of the configuration of AlN films on CrN in H13 steel substrate.

FIG. 20. Scanning electron microscopy images of the configuration of AlN films on CrN in H13 steel substrate associated with the chemical analysis by electron energy dispersion.

FIG. 21. Scanning electron microscopy images of the configuration of AlN films on CrN in 1045 H13 steel substrate associated with the chemical analysis by electron energy dispersion.

FIG. 22. Scanning electron microscopy high resolution images which show the structure of the AlN films on CrN in H13 steel substrate.

FIG. 23. X-ray diffraction spectrum, the CrN lines are identified in the diagram.

FIG. 24. X-ray diffraction spectrum corresponding to series B, the AlN lines are identified in the diagram.

FIG. 25. Scanning electron microscopy images of Cr films cross-sections followed by Cr₂O₃ on a HK40 steel substrate. The effect of the applied power is shown (a, b and c) and oxygen feeding in the mixture (d, e and f). (a) 50 W, (b) 60 W, and (c) 70 W, (d) 1-5 scc/min O₂ at 5 minutes and (f) 1-5 scc/min O₂ at 10 minutes.

FIG. 26. Mass increase curves generated in the thermobalance for uncoated samples, without graduating oxygen flow and graduating oxygen flow.

FIG. 27. Scanning electron microscopy images with energy dispersion spectra of samples exposed to catastrophic carburization in the thermobalance. (a) uncoated sample, (b) coated sample without graduating injection of oxygen in the flow and (c) coated sample graduating injection of oxygen in the flow.

FIG. 28. Scanning electron microscopy images of Al films cross-sections followed by Al₂O₃ on a HK40 substrate. The effect of pressure is shown: (a) 1 Pa, (b) >1 Pa, (c) >>1 Pa and (d) graduating oxygen.

FIG. 29. X-ray diffraction diagram of a HK40 steel substrate coated and exposed to an uncoated carburant atmosphere and exposed to the same carburant atmosphere (b) and with oxygen graduated coating (c).

FIG. 30. Mass increase curves generated in the thermobalance for uncoated samples, without graduating oxygen flow and graduating oxygen flow.

### TABLES

1. Diagnosis with Langmuir probe

2. Optical emission spectroscopy diagnosis.

3. Parameters for the introduction of oxygen to produce a chromia film.

4. Parameters for the introduction of oxygen for producing an alumina film.

5. Results of the electron temperature.

6. Results of the density of ions in the plasma.

7. Results of measurements with the Langmuir probe on the Al blank.

8. Reference for the experiments to study the pressure in the reactor.

9. Differences between experiments for CrN deposition.

10. Differences between experiments with CrN and AlN multilayer deposit.

### DESCRIPTION OF THE PROTOTYPE

For purposes of disclosing the prototype three functional sets have been considered which we call systems. These three systems are:

1. Gas extraction and supply system.

2. Power supply system.

3. Plasma analysis system.

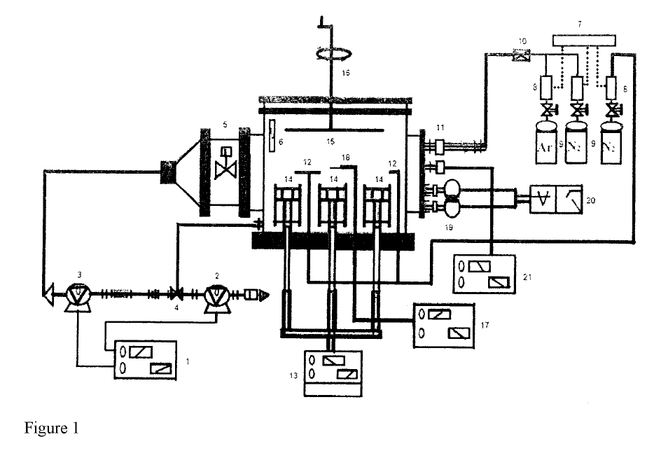

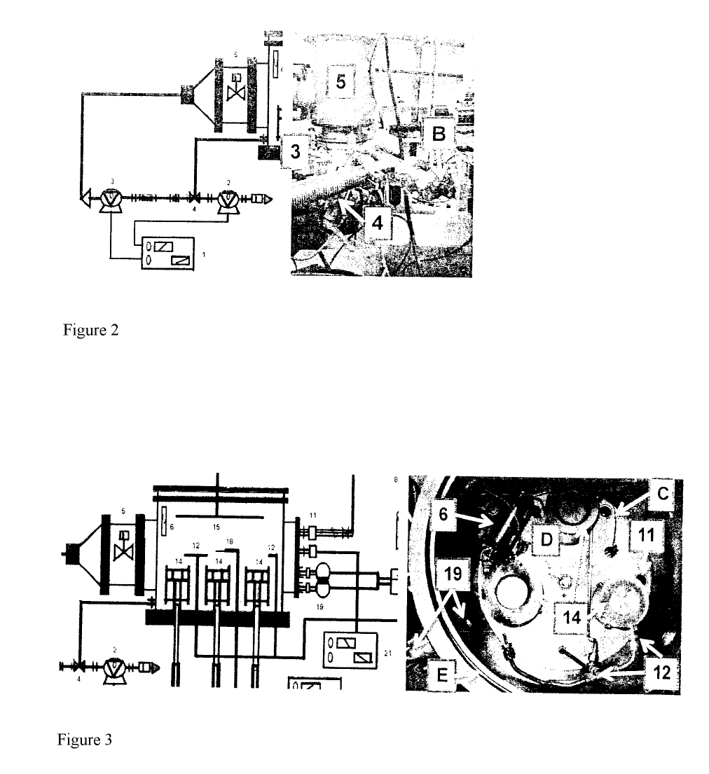

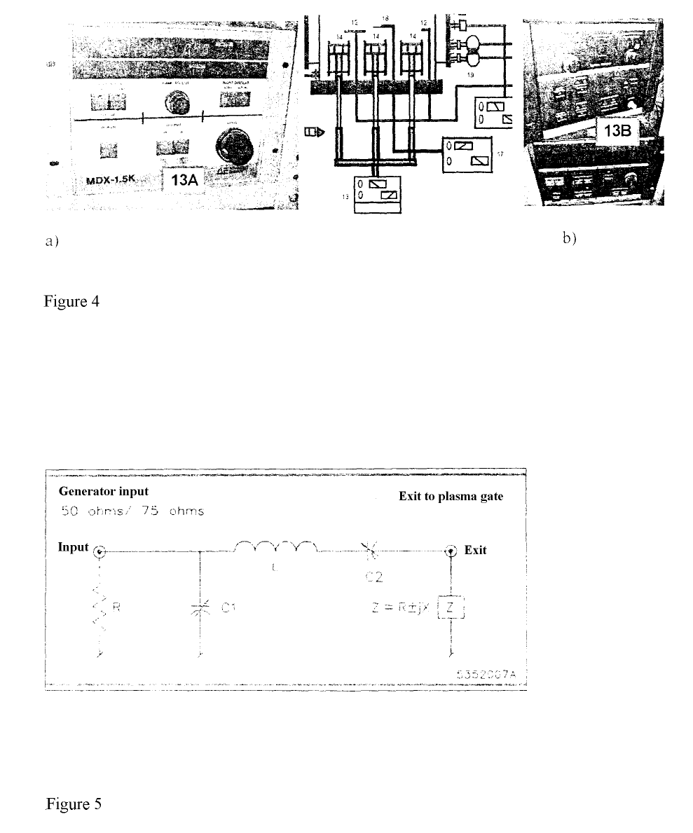

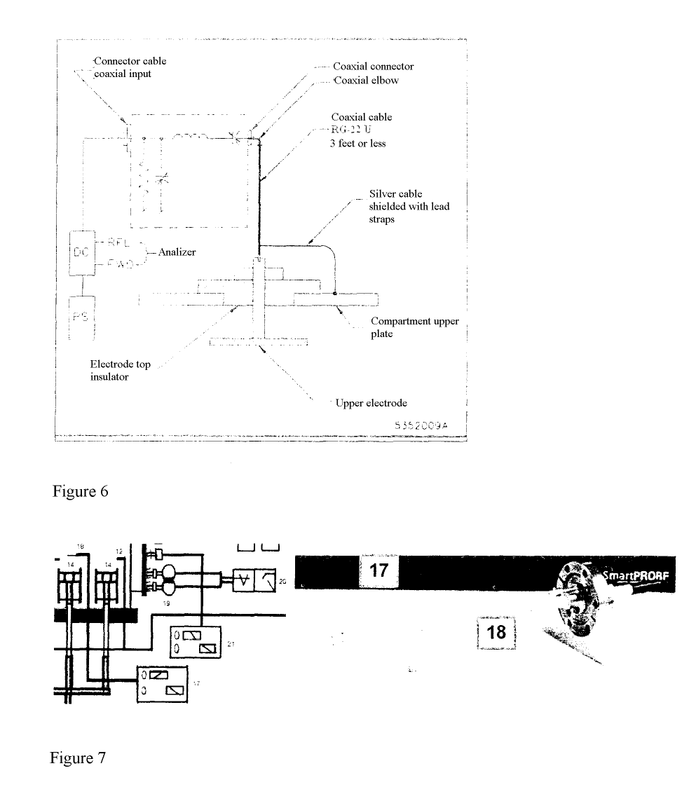

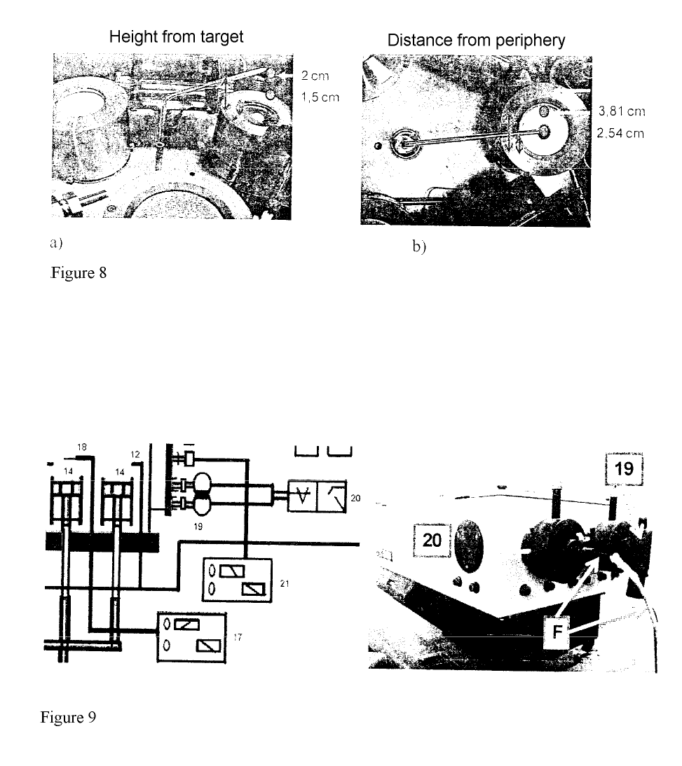

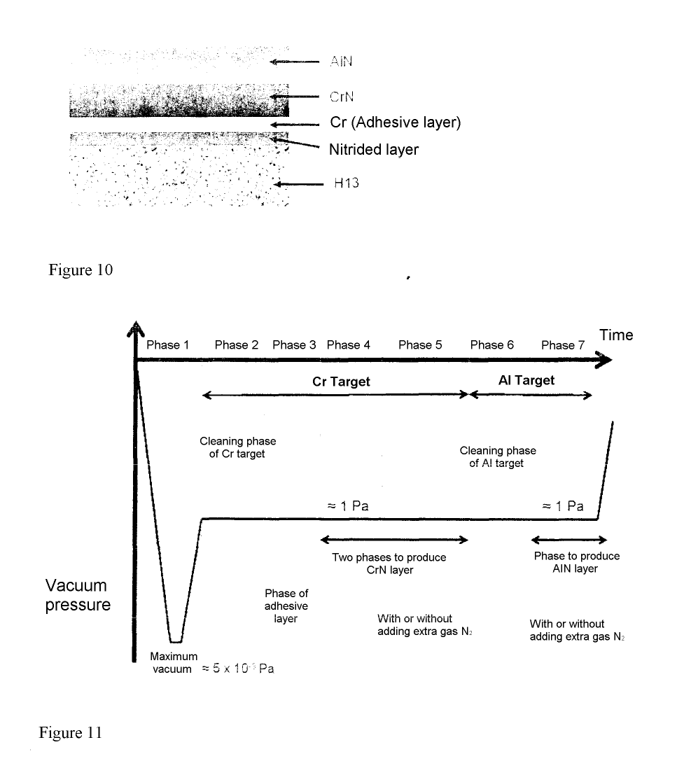

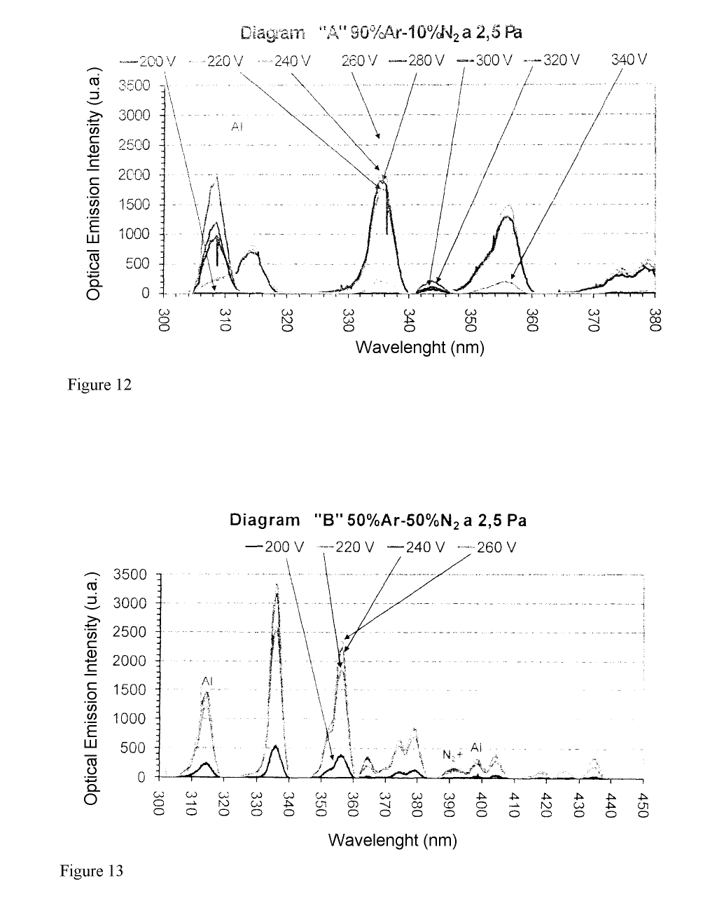

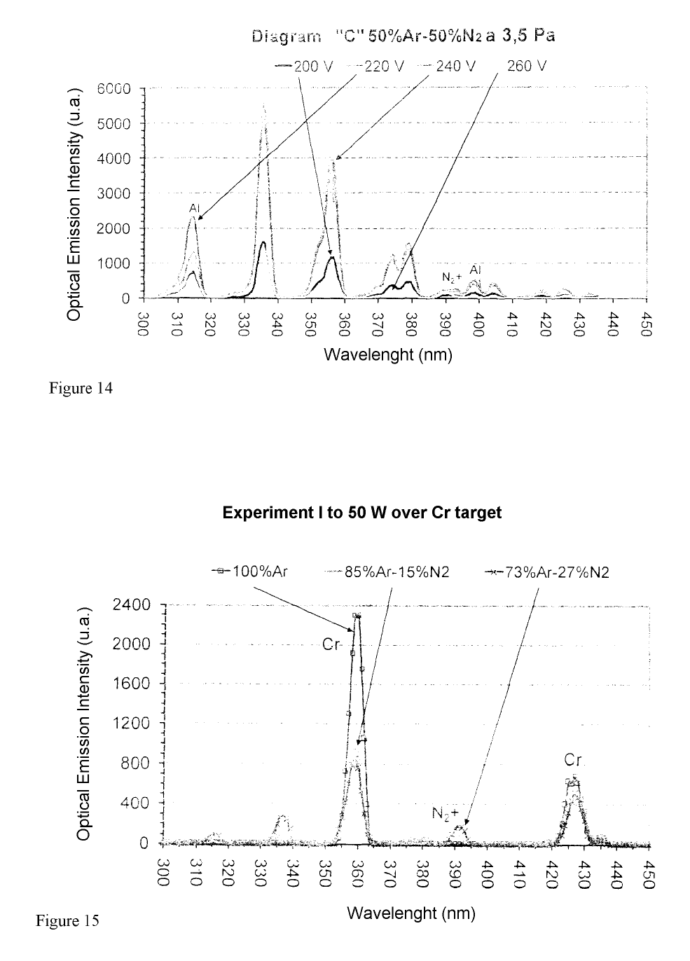

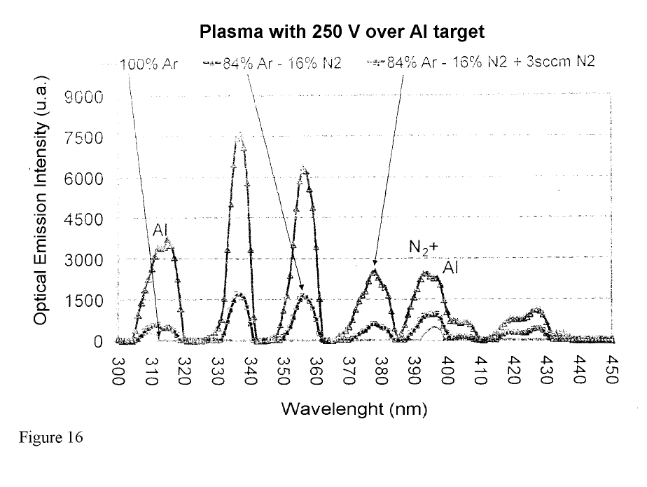

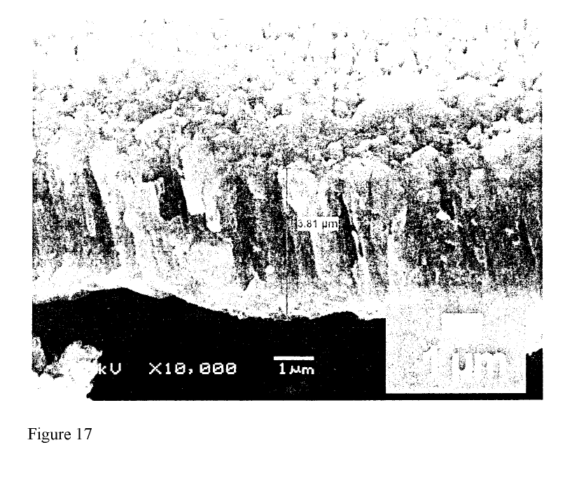

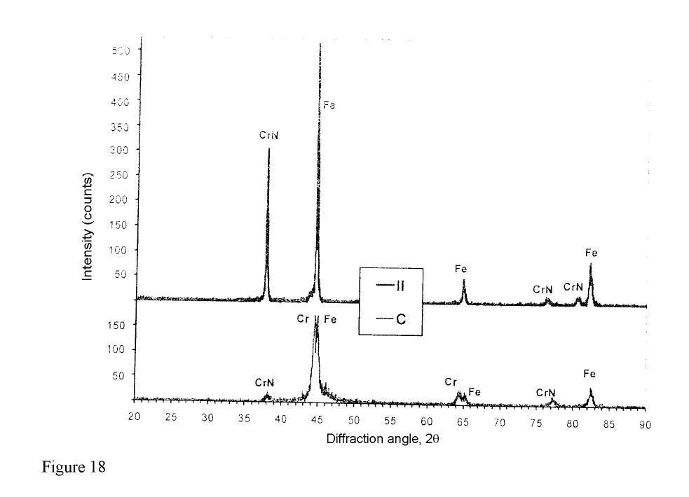

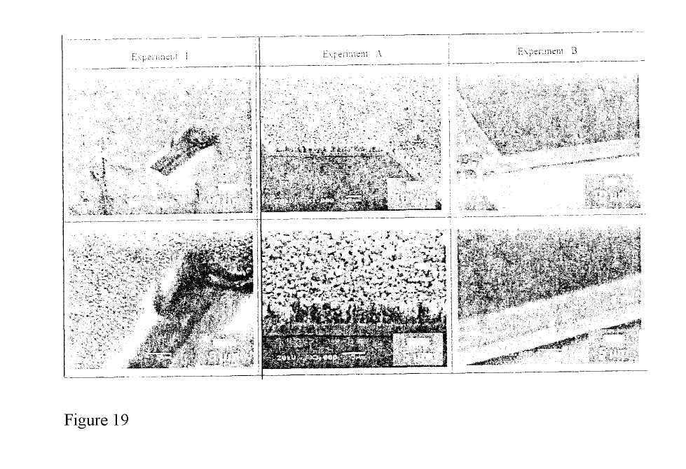

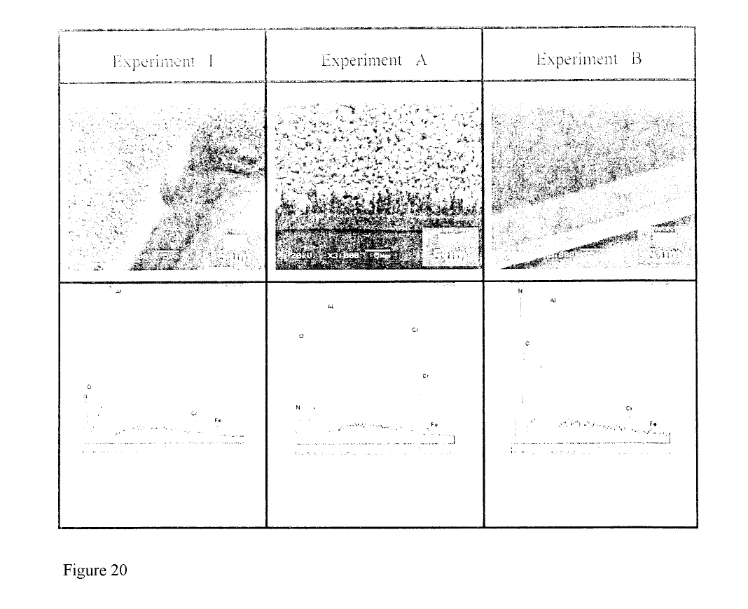

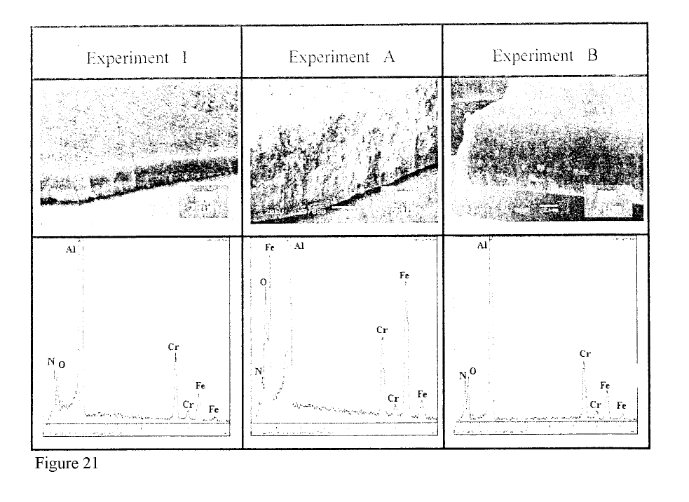

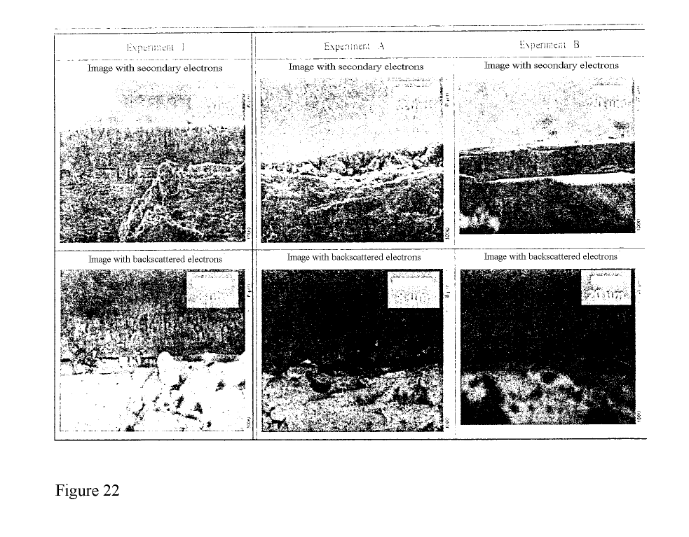

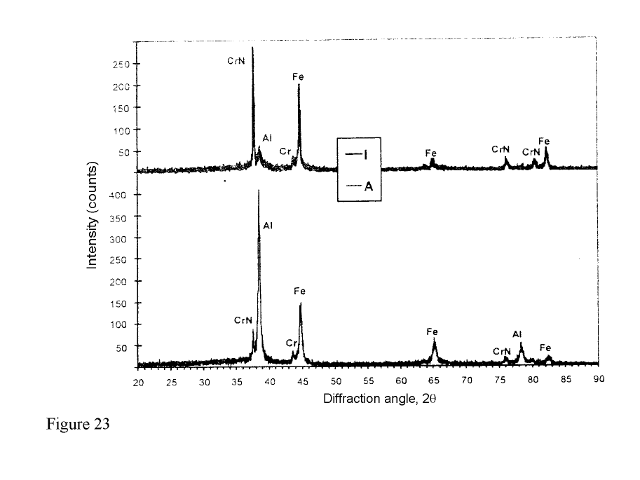

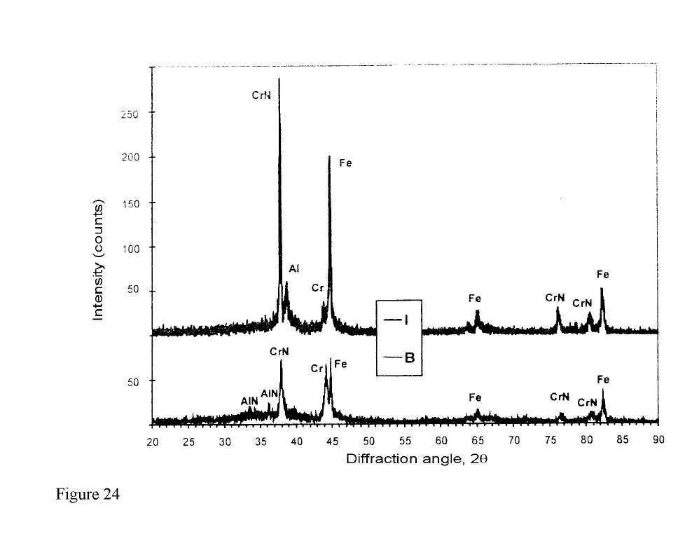

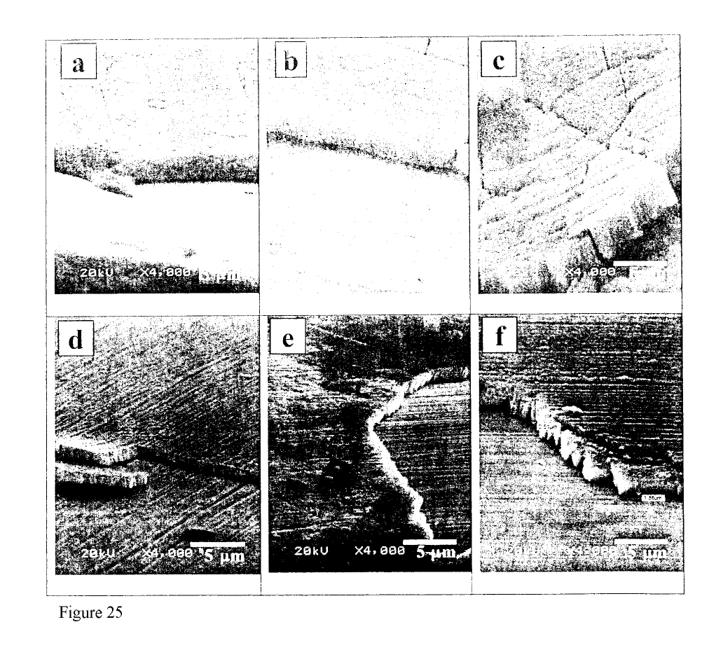

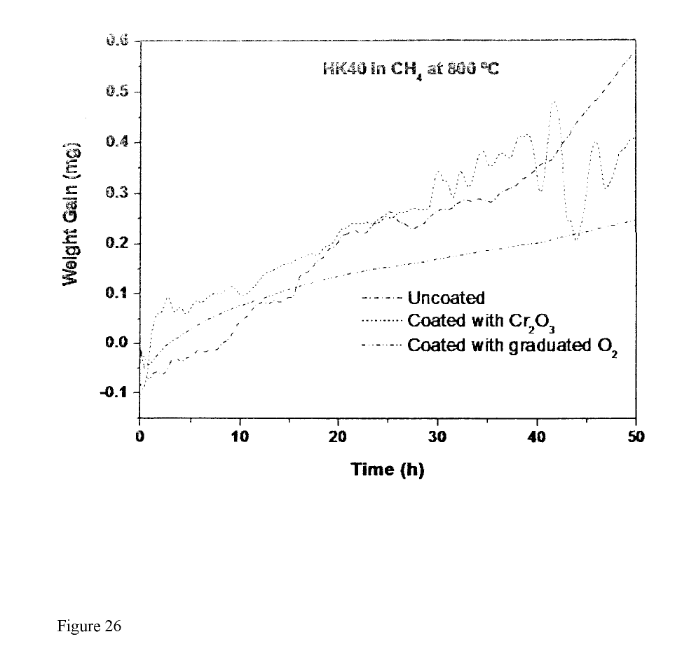

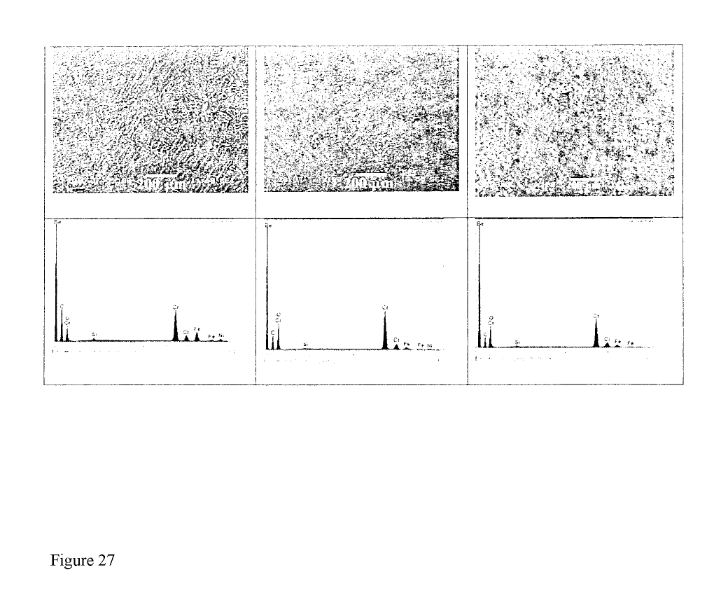

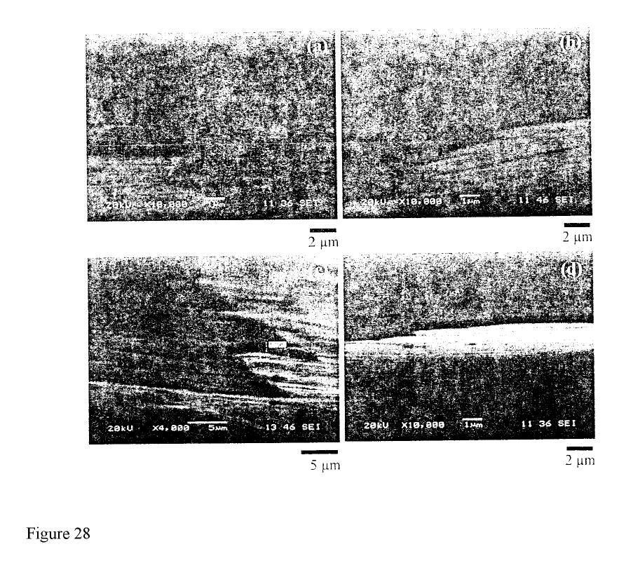

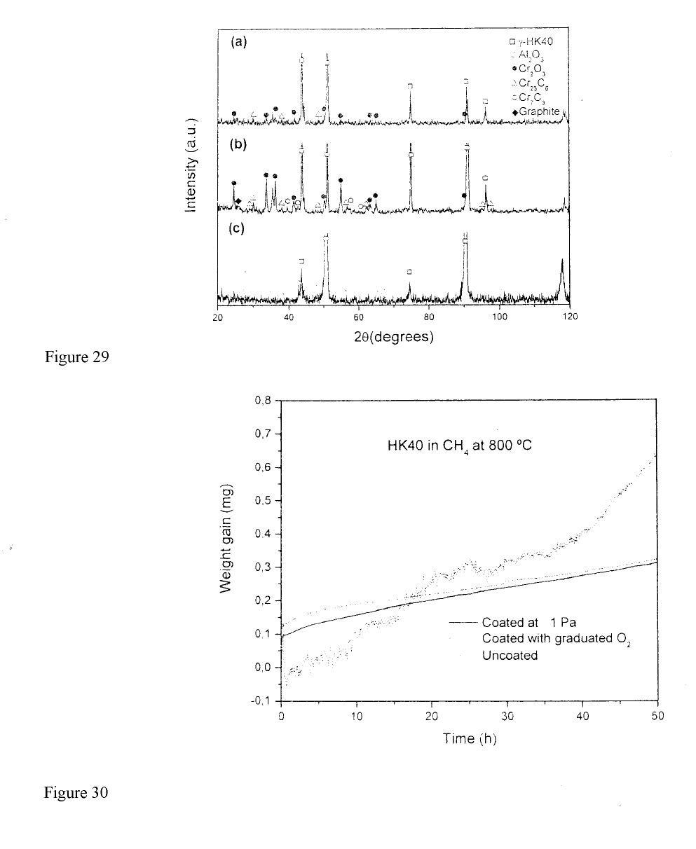

The components of these three systems of the reactor are depicted in FIG. 1. The gas extraction and supply system, numbered 1 to 12 (plus component 21); the power supply system, numbered 13 to 16, and the plasma analysis system, numbered 17 to 20.

Gas Extraction and Supply System

FIG. 1 depicts components 1 to 12 plus component 21, the function of this system is to extract gases from the chamber to produce the required vacuum, while maintaining the residence time of the gas mixture in the chamber so that the reaction between nitrogen and/or oxygen with metal elements such as Cr and Al takes place. Gas supply, heating of the chamber as well as of the substrate, which in this case is tool grade H13 steel, and pressure monitoring are considered parts of the same system. It has been considered to divide this system into four parts: 1) the subsystem of the pumps and attachments for gas extraction, 2) the subsystem for supplying the desired gases inside the reactor, 3) the subsystem for monitoring pressure and finally 4) the subsystem for controlling and monitoring temperature.

A schematic of the first subsystem is shown in the left part of FIG. 2. The mechanical pump (FIG. 2, component 2) performs a vacuum of up to 0.13 Pa (10⁻³ torr) allowing the turbomolecular pump to be put into operation (FIG. 2, component 3), which in turn could achieve a vacuum of up to 1.33×10⁻⁴ Pa (10⁻⁶ torr). Both pumps require a controller to which are connected; the on and off controller thereof, as well as the rotational speed of the turbomolecular pump. The controller contains internal sensors connected to the pumps and the power line to monitor proper operation of both.

Conductance—in units of volume transported per unit time (1/s)—, varies according to the gas flow rate as well as the nature of the gas. The net transfer of gas through a component connected to a high vacuum pump is proportional to the pressure difference across said component. The general formula of the conductance (C) is: C=Q/ΔP, where Q is the flow rate and ΔP is the difference in pressures. The valve 5 shown in FIG. 2 allows the serial operation of the mechanical and turbo pump. In our prototype design, the valve 5 allows to create vacuum in the chamber. By means of the rotational speed of the turbomolecular pump is possible to adjust the conductance and hence the residence time of gases in the chamber.

The second subsystem relating to the supply of gases, is formed mainly by mass flow controllers (FIG. 1, component 8) and their mixer (FIG. 1, component 10) as well as its command or controller (FIG. 1, component 7), which produces the setpoint for the supply of gas to be injected inside the chamber (FIG. 3, component 11), as well as tanks and gas supply lines. An important element in this invention was the duct supplying nitrogen or oxygen near the blanks (FIG. 3, component 12) which provided an important resource for the synthesis of nitride coatings or the formation of oxides. It has been considered the entry of mixtures with oxygen, which under appropriate conditions allows formation of oxynitrides with specific properties, or the formation of thermodynamically and mechanically stable stoichometric oxides at elevated temperatures, these properties can be achieved by the proper supply of gases into the chamber.

An interesting aspect is that the supply of the injected gasses as well as the specific supply area in the region near the blank, are significant variables for performing the depositions. Because of this, we considered that the appropriate supply of nitrogen or oxygen, with the proper dose, in a region near the blank allows the formation of thin layers of nitrides or oxides. We used tubes directly in the inner part to direct the flow of nitrogen or oxygen near the substrate, as shown in FIG. 3 component 12. Several experiments were performed to characterize the effect that the gas feed had in the generation of deposits that we wanted to develop. The supply of nitrogen or oxygen is carried out so as not to poison the blank, i.e., not to produce a film of oxides or nitrides onto the blank, thereby limiting the emission of metal from the blank.

Turning to the third subsystem regarding monitoring of pressure, the pressures of working conditions for the desired coatings were found to be between 13.33 Pa and 1.33×10⁻³ Pa (0.1 torr to 10⁻⁵ torr), whereby we used a Baratron high accuracy capacitive sensor (FIG. 1, component 2).

The components of the temperature control and monitoring subsystem are shown in FIG. 3. The lamps (FIG. 3, component 6) and thermocouples, labeled C in the same figure, allow control of the temperature in the chamber. Different combinations were considered until achieving the current configuration. This subsystem has a very good response from room temperature to 90° C. in relation to the heating of the chamber or samples, as well as for monitoring the process from room temperature to 400° C.

Coating Discharge and Generation System

This system, which in the scheme of FIG. 1 is represented by the numbers 13 to 16, is used to transport the energy supply for the plasma formation. It includes three unbalanced magnetrons (FIG. 4, components 14). In the prototype commercial unbalanced magnetrons were used. The structure of magnetrons is used for pulverizing metal pieces, we call these pieces blanks, in the case of the design we used Al and Cr blanks. There are also the controllers of the power source which is supplied to the magnetrons for pulverizing the blank and for plasma generation, which for this invention can be direct current, DC, (FIG. 4, component 13A) or radio frequency, RF, (FIG. 4, component 13B). In the design of the reactor it has been considered generating an extra potential difference (called “bias” voltage) to enhance generation of the coatings. Proper use of “bias voltage” is important for the formation of oxides. The sample holder (FIG. 1, component 15) and the device for rotating it (FIG. 1, component 16) are other components of this system, these components fasten the piece to be coated, called substrate. By means of a rotation it can be positioned at some distance above each of the magnetrons wherein the process shall take place, thus producing multilayer and multi-component structures. With this design the substrate to be coated is hidden by keeping it out of the plasma formation region. Subsequently, when the stability conditions are reached in the process, the substrates are moved by a rotation about the axis of component 16 shown in FIG. 1. The unbalanced magnetrons installed in the reactor can be powered by RF or DC, in order to generate and maintain the plasma. The RF power controller that was used for the prototype is of the brand Advanced Energy model RFX-600 (FIG. 4, component 13B) in addition to its capacitance controller ATX-600. Within the technical specifications of RF controller is that the output impedance it handles is 50Ω with a power of 600 W. It additionally handles a frequency of 13.56 MHz with a harmonic distortion at less than 50 dB and an accuracy at the value output which is greater between 3% of the reading or 2 W. Furthermore the principle of operation of the capacitance controller ATX-600, to which the radiofrequency power controller RFX-600 is connected, is based on an “L” diagram composed of two opposite sign capacitances and an inductance connected in series to the two capacitances. FIG. 5 shows the corresponding diagram. This diagram shows that the input provided by the radiofrequency energy controller, the RFX-600, provides a resistance of 50Ω or 75Ω. The operation of the capacitance controller is to make the output, which is traditionally the connection to the magnetron together with the blank, which can be represented as an impedance R±jX is converted to a constant of 50Ω or 75Ω through manipulation of the capacitances C₁ and C₂ inside the same.

The specific case of the connection made between the RFX-600 and the ATX-600 and this in turn to the magnetron in the chamber, is shown in FIG. 6. Here the “PS” is the radio frequency energy controller RFX-600 which outputs to the “DC” which is the capacitance controller ATX600, the capacitance value is set in order to regulate the power supplied to the magnetron with the least amount of reflected power; this is accomplished by finding an impedance 50Ω or 75Ω to the output.

The direct current controller that was also used for energy supply in the reactor is of the brand Advanced Energy model MDX-1.5K (FIG. 4, component 13A). For the MDX-1.5K, the selection methods for regulating the output may be by power, by current or by voltage. It is useful to use different sources for the synthesis of films under appropriate conditions. Thus, it has been possible to permute the sources and associate them with the synthesis of products with specific properties. For each case a switch was implemented to feed the magnetrons with DC or RF.

Two Kurt J. Lesker brand magnetrons model TRS2FSA and TM02FS10 of two inches type Torus 2 (FIG. 1 component 14) were installed in the magnetron. In addition, an unbalanced, three inch magnetron model A3CV-Ha of the brand AJA was installed.

Plasma Analysis System

The plasma analysis system, which in the scheme of FIG. 1 are components 17 to 20, is the one that allows monitoring of the process. This system consists of the Langmuir probe and optical emission spectrometer (EOE) both equipments being controlled from a computer.

The Langmuir probe and its data acquisition unit of the brand Scientific Systems where the model of both equipments is within the SmartProbe system, with which it is possible to monitor and analyze the values provided by the Langmuir probe. The Langmuir probe (FIG. 7, component 18) of the prototype can be positioned in the region of the plasma generated by each of the magnetrons, the positioning is performed when installing the same through the ports that the chamber comprises. FIG. 8 shows the reference for positioning the probe to the height and in relation to the radius of the magnetron blank. Plasma relevant information is obtained through the probe in real time. The information is obtained in regions relevant to the process. Among the technical features of this SmartPorbe system are that it can measure ion (nᵢ) and electron (nₑ) densities from 5×10⁸ to 5×10¹² cm⁻³ and electron temperature (Te) from 0.04 to 10 eV. For this, the resolution of the probe in terms of voltage is from about 25 mV and in terms of current is of 0.1 μA, using for this a reference voltage of 25 mV. The probe has an impedance greater than 100KΩ, wherein its capacitance for electrode compensation is of 50 pF. The probe tip is of tungsten with a length of 10 mm and a radius at the tip of 0.19 mm, which provides a surface area of contact with the plasma of 3.5 cm².

The Langmuir probe in conjunction with its data acquisition system and the software used, provides information on the parameters of plasma derived from the characteristic current-voltage (IV) curve, which is achieved by varying the voltage on the probe and measuring the resulting current. This makes it possible to obtain as parameters from the second derivative of the characteristic curve I-V, the plasma potential (Vₚ), the plasma floating potential (V_{f}), the electron temperature (Tₑ), the electron density (nₑ), ion density (nᵢ) and the Debye length (λD).

Through the optical emission spectrometer (FIG. 9, a component 20) the atmosphere is monitored in different regions of the reactor, this is done through the four ports destined for that purpose in the chamber. The light intensity, ranging from infra red through the visible to ultraviolet domains, is taken to the spectrometer using an optical fiber (FIG. 9, component F). The optical fiber is placed on the outside of the sight glasses therefore not affecting the process. The solid angle of vision of the optical fiber is 26°.

The optical emission spectrometer (EEO) is of the brand Jobin-Yvon model HR-640M which uses a data acquisition system which control is done at the module called Spectralink, of the same brand, with the basic modules, connected to the interface with the computer, as well as the photomultiplier model R-446 connected to the optical fiber probe (FIG. 9, component F). Among the most important technical specifications of the EOE is its focal length of 640 mm, having an opening F/6 with a window of 80×110 mm, where a spectrum range with wavelengths ranging from 190 nm to 700 nm is used, and wherein its resolution is better than 1.6 nm.

With this information it is possible to relate it with respect to reactor operation parameters such as the supply of the gases introduced, and the mixture that is provided, which result in the synthesis of the thin films with the functional characteristics required. With the prototype described several configurations of multi-component and nanostructured thin films have been made. As an example but not in a restrictive sense, special steel substrates: H13, HK40, 316L or 304, or carbon steel substrates 1045, in some cases the substrates are previously nitrided using an hybrid, patent pending nitriding process. Film architectures have been generated which are schematically shown in FIG. 10. This design allows improved tribological properties: improvement in friction and wear of mechanical components. Also the production of the oxide layer allows a marked improvement in carbon catastrophic corrosion resistance. The distribution of efforts to ensure adhesion of the films is performed by means of an adhesion layer, in this case it was made of Cr or Al. The synthesis of a graded layer of CrN on the Cr film has exhibited good mechanical properties. The synthesis of AlN on the CrN film is one of the variants that can be generated with the prototype. For catastrophic carbon protection also configurations of Cr/Cr₂O₃ and Al/Al₂O₃ have been designed.

Procedure for Manufacturing Thin Films

To produce the succession of layers shown in FIG. 10, the procedure described below is followed, the procedure is schematically illustrated in FIG. 11, the numerals of the referred components correspond to FIG. 1.

Procedure for Manufacturing Nitride Films

1. Conditioning the reactor shown in FIG. 1. Fix the steel substrate to be coated on the sample holder (15). The substrate must be clean and be secured using latex gloves to avoid contact with finger oil. Cleaning can be done with alcohol or acetone in an ultrasonic bath. The substrate position is set at 180° with respect to the magnetron (14) to be used.

2. Reaching a pressure of five thousandths of pascal in the system. For this vacuum level first using the mechanical pump (3), then, when a value of one pascal is reached, measured with a vacuum gauge represented by the numeral (21), start the turbomolecular pump (2) operation, until reaching five thousandths of pascal in the system.

3. Introducing Ar in the system until reaching a pressure of 1 Pa. Producing a direct current plasma with Ar for cleaning the Cr blank. Controlling and measuring Ar entry through the controller and flow meter represented by the numeral (7). Introducing at most 1 Nl/min at standard temperature and pressure (STP) conditions. Generating a plasma with a voltage of between 500 and 800V. Maintaining the plasma for 20 minutes to clean oxides formed on the blank.

4. Moving the substrate with the sample holder (15), to position it in front of the magnetron of Cr (14). The positioning is done accurately using the stepper motor represented by the numeral (16). At that point the start of the formation of the adhesion layer is considered, identified as step 3 in FIG. 11. Performing control of the power supply by power or current, see examples of power domains in Table 1.

5. Injecting the nitrogen for the formation of CrN. Starting with the injection of nitrogen from the gas mixture produced in the component represented by the numeral (10). Set the fraction of nitrogen in the mixture using flow controllers assigned with the numeral (8) from the setpoints marked with numeral (7). Examples of nitrogen domains in the mixture are shown in Table 2. This stage is represented as step 4 in FIG. 11.

6. Injecting the extra nitrogen in the vicinity of the sample. Independently supplying nitrogen by means of the component represented by the numeral (12). The fraction of extra nitrogen supply is metered into stages, and can reach 30% of the total mixture. Depending on the features for graduating the layer the nitrogen injection is conditioned. Terminating the process permuting the power supply to the aluminum magnetron represented by the numeral (14) in FIG. 1. This stage is represented as step 5 in FIG. 11.

7. Producing a DC plasma with Ar for cleaning the Al blank, thus eliminating the supply of nitrogen to the reactor. Introducing Ar to the system until reaching a pressure of 1 Pa. Controlling and measuring Ar entry by the controller and flow meter (7). Introducing at most 1 Nl/min at standard temperature and pressure (STP) conditions. Generating a plasma with a voltage of between 500 and 800V. Maintaining the plasma for 20 minutes to clean oxides formed on the blank. This stage is represented as Step 6 in FIG. 11.

8. Initiating the formation of AlN film. Moving the substrate in front of the Al magnetron (14). The positioning is done accurately using the stepper motor (16). Considering the beginning of this stage with the injection of nitrogen from the gas mixture produced in the component (10). Setting the fraction of nitrogen in the mixture using flow controllers assigned the numeral (8) from the setpoints marked with numeral (7). This stage is represented as step 7 in FIG. 11. For the formation of this film extra nitrogen can also be injected, as described in Section 6.

9. Complete the process. Stopping power supply to the magnetron (14), by means of the power source represented by the numeral (13). Setting the cooling conditions by means of the heating lamps shown with numeral (6).

Once the cooling cycle is completed turning off the lamps; stopping gas supply; closing the three-way valves shown with numeral (4); turning off the turbomolecular (3) and mechanical (2) pumps, via the controller (1); allowing entry of air through the valve (4), and then opening the chamber and removing the substrate from the sample holder (15).

Procedure for Manufacturing of Oxide Films

The manufacture of two types of oxides, Cr₂O₃ and Al₂O₃, is considered.

Procedure for Manufacturing Cr₂O₃

1. Follow the steps 1 and 2 of section Procedure for manufacturing nitride films.

2. Introduce oxygen to the chamber. Oxygen is produced in a mixture of Ar+x % O₂. Table 3 sets the conditions for changing the content of O₂ in the mixture, changes which produce a Cr₂O₃ layer without poisoning the blank.

3. Complete the process according to what is noted in point 9 of the previous section.

Procedure for Manufacturing Al₂O₃

1. Follow the steps 1 and 2 of the nitride films section.

2. Introduce Ar in the system until reaching a pressure of 3 Pa. Produce a direct current (DC) plasma for cleaning the Al blank. Monitor and measure the Ar entry through the controller and flow meter represented by the numeral (7) in FIG. 1. Adjust the entry of Ar up to 20 Ncc/min at standard temperature and pressure (STP) conditions. Change the plasma setpoint to generate by power control, assigning a power of 55 W.

3. Grade injection of oxygen in increasing ramps up to 3 Ncc/min (STP). The introduction of oxygen is performed by extra injection in the vicinity of the sample.

4. During the start of oxygen introduction generate an additional voltage in the steel substrate, “bias voltage”. The additional voltage is DC, of −100 V with respect to the chamber walls. Table 4 shows the conditions for the introduction of oxygen for forming chromia.

5. Finish the process according to what is stated in point 9 of section Procedure for manufacturing nitrides.

Characteristics of the Procedures

For the synthesis of the thin films the following parameters are set: the distance between the blank and the sample, the average temperature of the samples, the number and percentage of the introduced gases, the pressure inside the chamber, the values used for the source for supplying direct current, the revolutions of the pump, and finally having the whole period for each of the process stages.

The supply of energy to the magnetrons is performed by means of CD, for the formation of Cr films a power control was made, therefore setting the power setpoint, current and voltage are adjusted along the experiment. For aluminum emission the power supply is performed by voltage, accordingly adjusting the current and power. The pressure and residence time in the chamber is affected by the speed of the turbomolecular pump. The emission form of the blank in metal mode is controlled by adjusting the pressure and the gas residence time in the reactor.

The film properties are associated with items that result from the characterization of the atmosphere. The parameters for characterization by means of the Langmuir probe are shown in Table 1. Characterization was done by modifying the power, pressure, the height from the center of the blank and the distance from the periphery. The design of the prototype for positioning the probe is shown in FIG. 8, the height with respect to the blank and the distance from the periphery of the magnetron are shown in said figure.

TABLE 1

Probe Position (cm)

| | | |
|---|---|---|
| Process Parameters | Height | Distance |

| | Power | Pressure | from | from |
|---|---|---|---|---|
| Test | (W) | (Pa) | blank | periphery |
| 1 | 30 | 0.5 | 1.5 | 2.54 |
| 2 | 30 | 0.5 | 1.5 | 3.81 |
| 3 | 30 | 0.5 | 2 | 2.54 |
| 4 | 30 | 0.5 | 2 | 3.81 |
| 5 | 30 | 3 | 1.5 | 2.54 |
| 6 | 30 | 3 | 1.5 | 3.81 |
| 7 | 30 | 3 | 2 | 2.54 |
| 8 | 30 | 3 | 2 | 3.81 |

The elements for characterizing the atmosphere by EOE are shown in Table 2. The emission spectra were obtained considering the pressure, the gas mixture and the applied voltages. Three subgroups marked “A”, “B” and “C” were associated for the characterization. The emission spectra were obtained by means of an optical fiber located on the outside, as shown in FIG. 9, component F. The correlations between the structure and properties of the coatings were identified on the one hand and on the other the characteristics of the plasma as the emission as a function of wavelength.

TABLE 2

| Diagram | Test | Pressure (Pa) | % Mixture | Voltage (V) |
|---|---|---|---|---|
| A | 1 | 2.5 | 90%Ar—10%N | 200 |
| A | 2 | 2.5 | 90%Ar—10%N | 220 |
| A | 3 | 2.5 | 90%Ar—10%N | 240 |
| A | 4 | 2.5 | 90%Ar—10%N | 260 |
| A | 5 | 2.5 | 90%Ar—10%N | 280 |
| A | 6 | 2.5 | 90%Ar—10%N | 300 |
| A | 7 | 2.5 | 90%Ar—10%N | 320 |
| A | 8 | 2.5 | 90%Ar—10%N | 340 |
| B | 9 | 2.5 | 50%Ar—50%N | 200 |
| B | 10 | 2.5 | 50%Ar—50%N | 220 |
| B | 11 | 2.5 | 50%Ar—50%N | 240 |
| B | 12 | 2.5 | 50%Ar—50%N | 260 |
| C | 13 | 3.5 | 50%Ar—50%N | 200 |
| C | 14 | 3.5 | 50%Ar—50%N | 220 |
| C | 15 | 3.5 | 50%Ar—50%N | 240 |
| C | 16 | 3.5} | 50%Ar—50%N | 260 |

Table 5 shows electron temperature (Te) values in plasma measured with the Langmuir probe. In all cases it is observed that the Te is greater in the center. Position, pressure and power are significantly important parameters with respect to Tₑ. The associated results of the ion density measurements are shown in Table 6. It is observed that there are fewer species by reducing the internal pressure of the chamber. However, the species at each height of the volume at a 0.5 Pa pressure, remain more stable in terms of their quantity as those occurring at a higher pressure. With these results variations are obtained in the density of ions in the volume that are used for the synthesis of thin films. Based on this observation the coatings are made at a power and pressure which ensure a high Tₑ.

TABLE 5

| | | |
|---|---|---|
| | 30 Watts | 30 Watts |
| Distance (cm) | 0.5 Pa | 3 Pa |

| Height | Width | Te (eV) | Te (eV) |
|---|---|---|---|
| 1.5 | 2.54 | 6.195 | 5.234 |
| 1.5 | 3.81 | 6.058 | 4.992 |
| 2 | 2.54 | 5.692 | 4.117 |
| 2 | 3.81 | 5.232 | 3.670 |

TABLE 6

| | | |
|---|---|---|
| Distance (cm) | 30 W 0.5 Pa | 30 W 3 Pa |

| Height | Width | ni (#/cm³) | ni (#/cm³) |
|---|---|---|---|
| 1.5 | 2.54 | 1.33E+11 | 1.45E+11 |
| 1.5 | 3.81 | 1.27E+11 | 1.55E+11 |
| 2 | 2.54 | 1.34E+11 | 1.12E+11 |
| 2 | 3.81 | 1.31E+11 | 1.92E+11 |

From the analysis of the information generated by the Langmuir probe associated with plasma behavior on each of the blanks, their tendency was observed both with the change of the injected gas mixture as well as the power delivered. This was analyzed both on the chromium blank and the aluminum blank. Based on this information the power domains transferred to the plasma producing Tₑ appropriate for the synthesis of nitrides were determined. We found that for powers of 50 W a decrease in nᵢ is expressed. For the case of Al emission, it was found that the control voltage produces appropriate Tₑ and nᵢ for the deposition. Table 7 shows the results obtained for Al emission plasmas with the voltage power supply. For these cases, the design of the prototype considered the injection of N₂ near the blank.

TABLE 7
For Al blank

| | Plasma with: | Te (eV) | ni (#/cm³) |
|---|---|---|---|
| Blank Cleaning | 100%Ar & 450 V | 1.20 | 4.11E+9 |
| | 100%Ar & 405 V | 0.34 | 1.71E+9 |
| | 84%Ar—16%N2 & 450 V | 0.94 | 2.74E+9 |
| AlN Layer | 84%Ar—16%N2 & 428 V | 1.49 | 2.61E+9 |
| | 84%Ar—16%N2 & 405 V | 1.46 | 2.80E+9 |

Plasma characterization by optical emission spectroscopy allows to identify the emissive systems of atoms and molecules in the plasma and correlate them with the structures of thin films. FIG. 12 shows examples of emissions produced at 2.5 Pa and with mixtures of 90% Ar-10% N₂. In the figure it is evident the effect of voltage in relation to the light emission. The intensity of the light emission increases significantly between 200 V and 260 V, after 260 V the emission does not grow substantially in the spectral domain considered, these evidences allowed to set values of the appropriate voltages for the synthesis of thin films in the process.

FIG. 13 shows the emissive system of atoms and molecules in the plasma generated by direct current by varying the content of Ar and N₂ in the mixture. This set of results highlights the effects of voltage on gas mixtures. Based on these results the emissions have been used for relating them to the synthesis of nitrides. Examples of variations in the emission spectra as a function of pressure are shown in FIG. 14. In these domains, the transition from the metal emission mode to the reactive one is relevant. The figure shows the emission spectrum at a pressure of 3.5 Pa.

The variation of the emission spectra for the synthesis of the Cr graded layer is shown in FIG. 15. In this case it has been found convenient to perform the power control: 50 W. The sequence of steps for forming Cr to CrN graded films is depicted in said figure. In this case the transition may be achieved through modification of the gas mixtures. The figure shows the shift from metallic mode to reactive mode, which runs from Cr emission into the atmosphere to the production of CrN in the substrate.

The effect of N₂ injection in the vicinity of the Al blank on the emission spectrum is shown in FIG. 16. An increase corresponding to the first positive system of the nitrogen molecule appears in the spectrum, particularly for □=394.4 nm, wavelength corresponding to the electronic transitions of the nitrogen molecule. It has been found that the presence of this spectral line is very important to ensure the synthesis of nitrides.

Multilayer Coatings

The configuration of multilayer and multi-component films is schematically shown in FIG. 10. In the context of this embodiment, the following configurations were achieved:

I. Nitride formation
1. CrN graduated
2. AlN on CrN and
3. AlN nanostructured on Al.

II. Formation of oxides
1. Cr₂O₃ compact on Cr and
2. Al₂O₃ on Al.

I. Nitride formation

1. Graded CrN

Table 8 shows the characteristics of procedures for obtaining a CrN film. In this case the film formation is performed by means of power control using a direct current power supply. To demonstrate the effect of nitrogen supply near the blank, the same table 9 presents the experimental data for which no extra provision of N₂ was made, the information on this experiment is presented in the column referenced as C.

TABLE 8

| Experiment: | II | C |
|---|---|---|
| Coating: | CrN | CrN |
| Blank: | Cr | Cr |
| Cr blank power: | 420 V | 58 W |
| Cr deposition time (min): | 90 | 60 |
| Extra N2 supply on Cr | Yes | No |
| blank | | |
| % deposition time | 150% | 100% |

FIG. 22 shows an image of the thin film generated by high resolution scanning electron microscopy (SEM). FIG. 23 shows the X-ray diffraction spectrum of the coated piece. In the diffraction pattern the CrN spectral lines can be seen. Contrast is observed with respect to the CrN emission intensity for the nitrogen supply experiment, labeled II, and without nitrogen supply, labeled with a C.

2. AlN on CrN Configuration

Table 9 shows the characteristics of procedures for obtaining configurations of AlN layers on CrN. In this group of experiments the power supply was performed by CD in power control mode. In relation to the reference marked as I in the Table, the duration of treatment and the manner of injection of nitrogen in the region between the magnetron and the substrate were changed in group A and B, see FIG. 3.

TABLE 9

| Experiment: | I | A | B |
|---|---|---|---|
| Coating: | CrN & AlN | CrN & AlN | CrN & AlN |
| Blank: | Cr & Al | Cr & Al | Cr & Al |
| Cr blank power (W): | 50 | 48 | 50 |
| Cr deposition time (min): | 60 | 90 | 60 |
| Extra N2 supply on Cr | Yes | Yes | Yes |
| blank: | | | |
| Al blank power (V): | 450 | 450 | 450 |
| Al deposition time (min): | 30 | 45 | 30 |
| Extra N2 supply on Al | No | No | Yes |
| blank: | | | |
| % deposition time | reference | 150% | 100% |

FIG. 24 shows the configuration of AlN films on CrN on a substrate of H13 steel. FIG. 25 associates the image of the film configuration cross-section with microanalysis by means of energy dispersion spectrum which identifies the elements in thin films. FIG. 26 shows structural details using a larger magnification, in this case the coating was performed on a 1045 steel substrate under the NOM denomination.

In connection with changes in operating parameters reported in Table 9, it is shown the effect on the structure of the films. FIG. 27 shows high resolution electron microscopy images which display the structure of the films. The AlN compact layer matches the characteristics reported in the series B.

FIG. 28 shows the X-ray diffraction spectrum on the basis of the parameters reported in Table 9, series I. In the diagram CrN lines are identified. FIG. 29 shows, in relation to the X-ray diffraction spectrum of the structure produced in the series B, that the diffraction spectrum reveals the formation of AlN on the surface of the piece.

II. Oxide Formation

1. Cr₂O₃ Compact on Cr

Table 3 shows the experimental values which allow to produce a Cr layer followed by a stoichiometric oxide layer. For the formation of a succession of Cr/Cr₂O₃ thin films without poisoning the blank, the steps referred to in the process for the formation of Cr₂O₃ films was followed.

TABLE 3

| | Cr Adhesion Film | | | | | | | | |
|---|---|---|---|---|---|---|---|---|---|
| | | | | Voltage | Cr₂O₃ Film | | | | |
| | Power | Time | Ar | “Bias” | Pressure | Power | Time | O₂ | Ar |
| Sample | (W) | (min) | (sccm) | (V) | (Pa) | (W) | (min) | (sccm) | (sccm) |
| 1 | 50 | 30 | 20 | 0 | 1.5 | — | | | |
| 2 | | | | | 2 | — | | | |
| 3 | | | | | 3 | — | | | |
| 4 | | | | −100 | 1.5 | — | | | |
| 5 | | | | −300 | | | | | |
| 6 | | 5 | | 0 | | 50 | 60 | 5 | 20 |
| 7 | | | | | | 60 | | | |
| 8 | | | | | | 70 | | | |
| 9 | | | | | | 50 | 10 | 1-5 | |
| 10 | | | | | | | 5 | | |
| 11 | | | | | | | 2.5 | | |

FIG. 25 shows sections in the configuration of Cr₂O₃ films on Cr on an HK40 steel substrate. The images depict the effect of the applied powers and the way of feeding oxygen into the reactor. The graph of FIG. 26 shows the effect of the oxide film in corrosive environments with methane at 800° C. The graph shows the effect of compact oxide on the surface over catastrophic carbon corrosion in an HK40 special steel. The mass increase is much lower with respect to the flow of carbon in uncoated HK40 steels, as represented in the same figure. The carbon flux into the steel is limited by the oxide film thus formed.

FIG. 27 shows images generated by scanning electron microscopy accompanied by energy scattering spectra of the electrons. There are shown the case of an uncoated HK40 steel sample (a), a coated sample without graduating oxygen feed (b), and a coated sample graduating the injection of oxygen in the mixture (c). All samples presented in the figure were exposed at 800° C. in a mixture of CH₄+Ar for 50 h.

2. Al₂O₃ on Al

Table 4 shows the values of experiments where the Al configuration is produced followed by an Al₂O₃ film on a HK40 steel substrate. For forming the succession of Al/Al₂O₃ thin films without poisoning the blank, the steps referred to in the process for forming Al₂O₃ films were followed. Table 4 shows the values that were considered for the formation of films.

TABLE 4

| | | | | Working | Voltage | Deposition | |
|---|---|---|---|---|---|---|---|
| | | Atmosphere | Power | Pressure | “Bias” | Period | Surface |
| Coating Type | Sample | (sccm) | (W) | (Pa) | (V) | (s) | Finish |
| Adhesion | 1 | 20 Ar | 55 | 3 | | 900 | Specular |
| Layer | | | | | | | Surface |
| | 2 | 20 Ar | 55 | 3 | | 900 | Specular |
| | | | | | | | Surface |
| Adhesion | 3 | 20 Ar | 55 | 3 | 0 | 900 | Specular |
| Layer + | | 20 Ar + | 55 | 3 | 0 | 1800 | Surface |
| Oxide | | 1-3 O₂ | | | | | |
| Film | 4 | 20 Ar | 55 | 3 | −100 | 900 | Specular |
| | | 20 Ar + | 55 | 3 | −100 | 1800 | Surface + |
| | | 1-3 O₂ | | | | | TGA |

FIG. 28 shows the configuration of Al₂O₃ films on AlN on an HK40 special steel substrate. The effect of pressure on the morphology of the film is shown. FIG. 29 shows the X-ray diffraction diagram of the HK40 steel substrate, with Al₂O₃/Al coating exposed to a corrosive atmosphere comprising a mixture of methane and Ar at a temperature of 800° C. (a), uncoated and exposed to the same carburant atmosphere (b) and with a coating graduating oxygen feed (c). Carbon activity in methane selected mixtures corresponds to that of environments similar to those generated in direct reduction plants or in the processing of hydrocarbons. For the case of uncoated steel, the X-ray diagram shows the formation of M₂₃C₆, M₇C₃ type carbides, carbides that are known as precursors in the disintegration of the steel.

FIG. 30 shows the weight gain curves produced in environments with Ar-methane mixtures at 800° C. for uncoated HK40 steel (a), with coating not graduating the entrance of oxygen (b) and graduating the entrance of oxygen. As in the case of chromium oxide, the graph shows the surface effect of compact oxide on carbon catastrophic corrosion in an HK40 special steel. The mass increase is much lower with respect to the flow of carbon in uncoated HK40 steels, represented in the same figure. The carbon flux into the steel is limited by the oxide film thus formed.

Having disclosed the invention as above, it is claimed as property what is contained in the following claims:

1. A process for coating multilayer and multi-component thin films on substrates of various materials, characterized by comprising the steps of:
a) Fixing the substrate to be coated on the sample holder;
b) Reaching a five thousandths of pascal pressure in the system and producing a direct current plasma with Ar for cleaning the Cr blank. Introducing Ar in the system until reaching a pressure of 1 Pa. Controlling and measuring the Ar entry through the controller and flow meter;
c) Introducing 1 Nl/min at standard conditions of temperature and pressure (STP) and generating a plasma with a voltage of between 500 and 800V. Maintaining the plasma for 20 minutes to clean oxides formed on the blank;
d) Moving the substrate with the sample holder to position it in front of the Cr magnetron and performing the control of energy supply by power or current;
e) Injecting nitrogen for the formation of CrN. Starting with the injection of nitrogen from the gas mixture produced;
f) Setting the nitrogen fraction in the mixture using the flow controllers, injecting the extra nitrogen in the vicinity of the sample;
g) Swapping the power supply to the aluminum magnetron; and
h) Separately injecting nitrogen for the production of AlN.

2. The process according to claim 1, wherein a supply of direct current or a supply of radio frequency with the appropriate impedance adjustment is alternated in the reactor.

3. The process according to claim 1, wherein the drag flow in the vacuum pumps is adjusted by adjusting the conductance and hence the residence time of gaseous mixtures in the reactor.

4. The process according to claim 1, wherein the temperature of the chamber is adjusted through the emission of radiation from the lamps inside the reactor, the temperature adjustment being performed by means of thermocouples.

5. The process according to claim 1, wherein the formation of nitrides is related to the emission of spectral lines in the plasma and of the species emitted by the blank.

6. The process according to claim 1, wherein the gas mixtures in the process as well as the pressure are adjusted according to the measurement of light emission and electron density.

7. The process according to claim 1, wherein the formation of a chromia film, Cr₂O₃, is performed by gradual injection of oxygen into the chamber without the formation of the hysteresis cycle and without poisoning the blank.

8. The process according to claim 1, wherein the formation of an alumina, Al₂O₃, film on an Al adhesion layer is generated through the application of a “voltage bias”, without the formation of the hysteresis cycle and without poisoning the blank.

9. The process according to claim 1, wherein the formation of an alumina, Al₂O₃, film is performed by metered injection of oxygen in the gas mixture without the formation of the hysteresis cycle and without poisoning the blank.

10. An apparatus for carrying out the coating of multilayer and multi-component thin films on substrates of various materials, characterized by comprising a mechanical and turbomolecular pump controller, a mechanical pump, a turbomolecular pump, a three-way and three-position valve, a straight angle valve, a heating lamp, a mass flow controller command, mass flow controllers, gas tanks, a gas mixer, a mixed gas supply, a nitrogen supply near the blanks, a direct current or radio frequency source, unbalanced magnetrons, sample holder, a rotation of the sample holder, a Langmuir probe data acquisition unit, a Langmuir probe, a photomultiplier, monochromator or optical emission spectrometer and pressure gauges.

11. A coating characterized by comprising multilayer and multi-component thin films for coating substrates of different materials.

12. The coating according to claim 11, wherein the multilayer film comprises a chromium layer and a layer of a stoichiometric form of chromium oxide.

13. The coating according to claim 11, wherein the multilayer film comprises an aluminum layer and a layer of a stoichiometric form of aluminum oxide.

14. The coating according to claim 11, wherein the multilayer film comprises an aluminum layer and an aluminum nitride layer.
